(19) United States
(12) Patent Application Publication
(10) Pub. No.: US 2010/0088569 A1
(43) Pub. Date: Apr. 8, 2010

(54) Packet Retransmission

(75) Inventors: Massimo Sorbara, Freehold, NJ (US); Julien D. Pons, Crateret, NJ (US); Ravindra M. Lambi, Old Bridge, NJ (US)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: IKANOS COMMUNICATIONS, INC., Fremont, CA (US)

(21) Appl. No.: 12/573,742

(22) Filed: Oct. 5, 2009

Related U.S. Application Data
(60) Provisional application No. 61/102,859, filed on Oct. 5, 2008.

(51) Int. Cl. H04L 1/18; H04J 3/24; H03M 13/00

(52) U.S. Cl. 714/751; 370/474; 714/752; 714/E11.001

(57) ABSTRACT

Embodiments disclosed herein include systems and methods of packet retransmission. More specifically, at least one nonlimiting example of a method includes receiving data from above a γ (gamma) interface, the data being identified as protected or not protected data; and storing the protected fragment in a retransmission queue included in a transport protocol specific transmission convergence layer.

### CROSS REFERENCE

This application is claims the benefit of copending U.S. Provisional patent application entitled “Packet Retransmission Method for DSL Systems” filed on Oct. 5, 2008 and accorded Application Ser. No. 61/102,859, which is entirely incorporated herein by reference.

### BACKGROUND

1. Technical Field

This application relates to digital subscriber line (DSL) systems and specifically to systems and methods for the retransmission of packets in a DSL system.

2. Background Information

This application defines a possible retransmission method for use in VDSL and ADSL systems. The goal of this application is to find an acceptable balance regarding roundtrip delay, support for traffic differentiation, and minimum impact on operations, and management relative to those in the current proposals under consideration. To achieve this, we derive elements from the retransmission proposals for operation above the TPS-TC that enable traffic differentiation and elements from the retransmission operation in the PMS-TC that facilitate lower round trip delay to form a unified retransmission method with improved operation.

In this paper, we focus discussion only on the transport of packets (e.g. Ethernet packets) using the Packet Transfer Mode Transmission Convergence (PTM-TC) mechanism defined in ADSL2/2plus and VDSL2. Although the principles of operation are very similar, the details for retransmission operation with the transport of ATM cells are addressed separately from this paper. The retransmission operation described in this paper is also specific to operation on a single DSL link without the use of Ethernet Bonding immediately above the retransmission layer; retransmission operation with Ethernet Bonding is addressed separately from this paper.

### SUMMARY

Embodiments disclosed herein include systems and methods of packet retransmission. More specifically, at least one nonlimiting example of a method includes receiving data from above a γ (gamma) interface, the data being identified as protected or not protected data; and storing the protected fragment in a retransmission queue included in a transport protocol specific transmission convergence layer.

Additionally, embodiments included herein include systems for data retransmission. A nonlimiting example of a system includes a retransmission and transport protocol specific-transmission convergence (TPS-TC) layer configured to receive data from above a γ (gamma) interface; and a retransmission queue in the retransmission and TPS-TC layer configured to store the protected fragment in a retransmission queue included in a transport protocol specific transmission convergence layer.

Other systems, methods, features, and advantages of this disclosure will be or become apparent to one with skill in the art upon examination of the following drawings and detailed description. It is intended that all such additional systems, methods, features, and advantages be included within this description and be within the scope of the present disclosure.

### BRIEF DESCRIPTION

Many aspects of the disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views. While several embodiments are described in connection with these drawings, there is no intent to limit the disclosure to the embodiment or embodiments disclosed herein. On the contrary, the intent is to cover all alternatives, modifications, and equivalents.

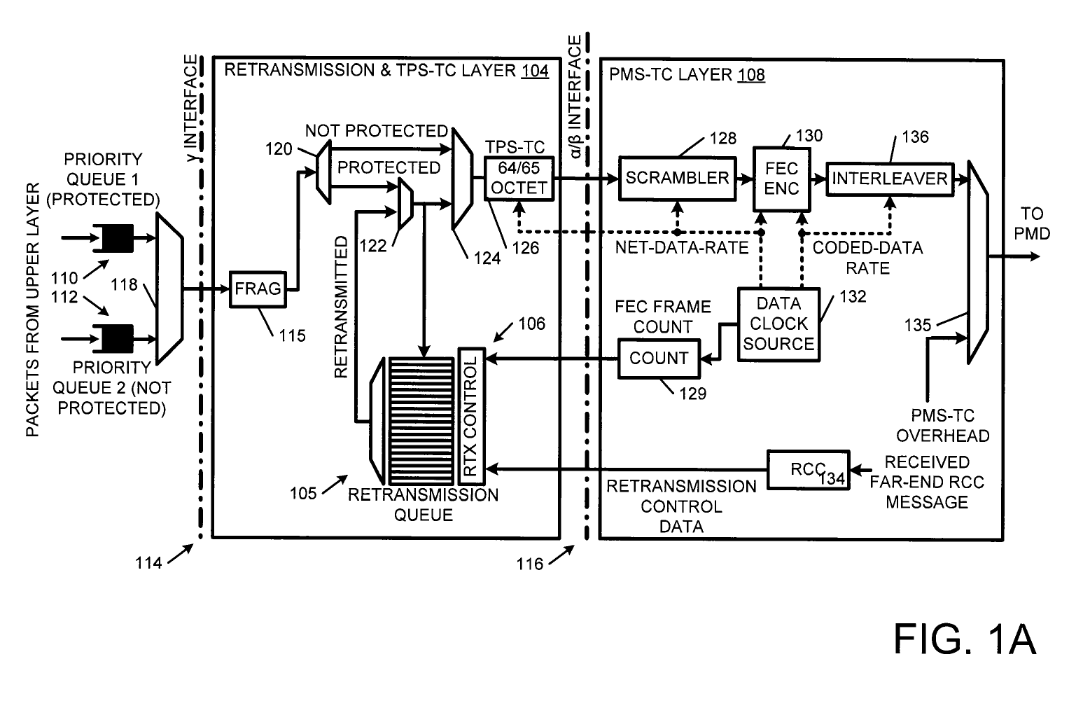

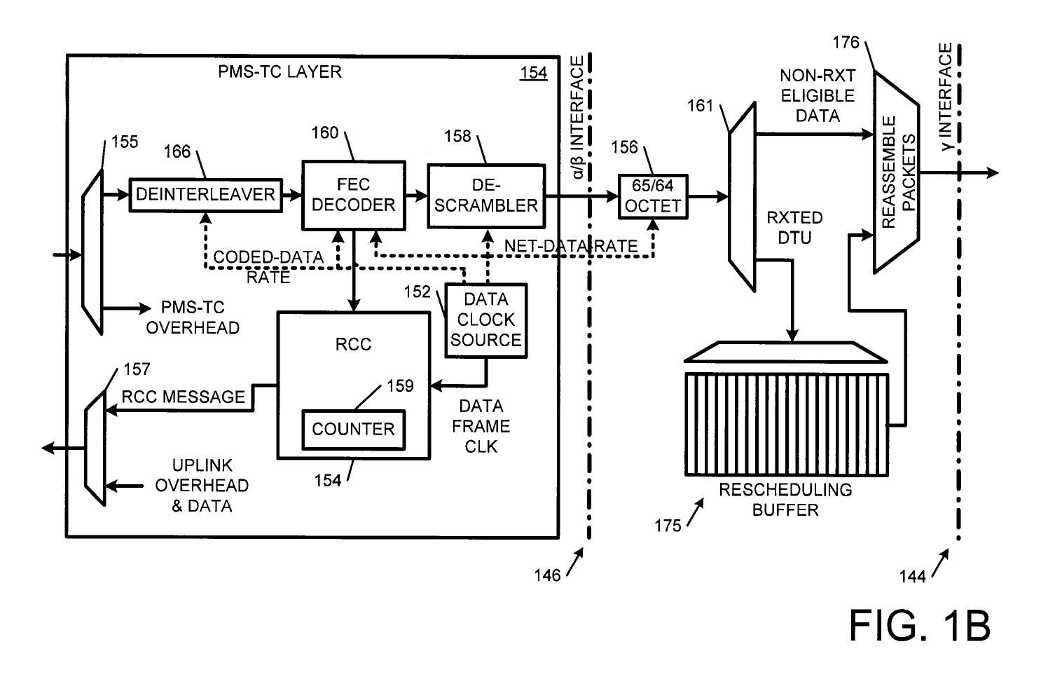

FIG. 1A illustrates an example embodiment of a computing system, illustrating a transmitter reference model with a retransmission component on a single latency path.

FIG. 1B illustrates an example embodiment of a computing system on a far-end for determining error in data received from the computing system from FIG. 1A.

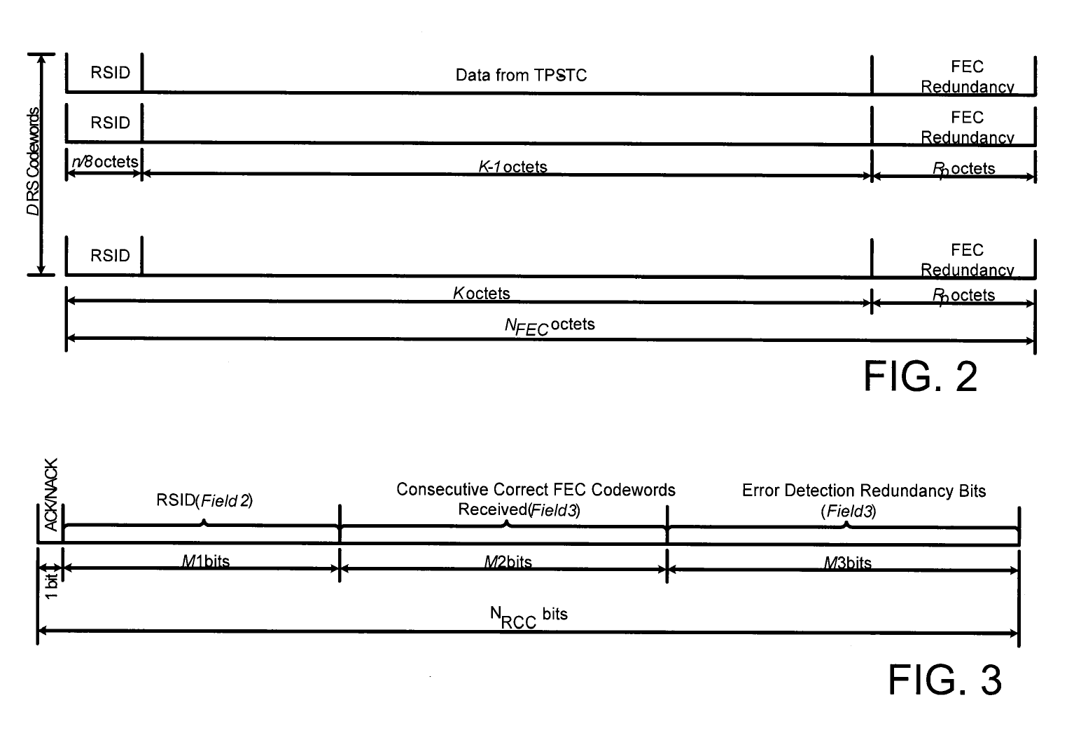

FIG. 2 illustrates an example forward error correction (FEC) codeword block structure, such as may be utilized in the system of FIG. 1A.

FIG. 3 illustrates an example retransmission control channel message frame structure, such as may be utilized in the system of FIG. 1A.

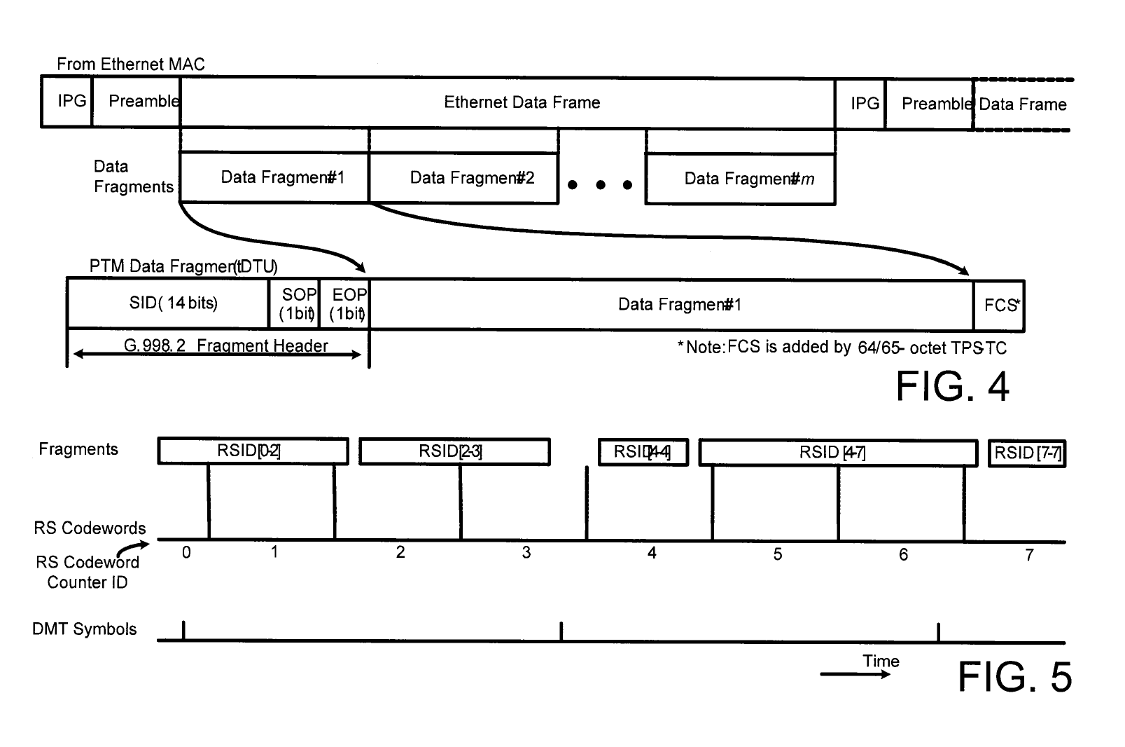

FIG. 4 illustrates an example packet transfer mode (PTM) fragment structure, such as may be utilized in FIG. 1A.

FIG. 5 illustrates an example mapping of a Reed-Solomon codeword timing counter, such as may be utilized in the system of FIG. 1A.

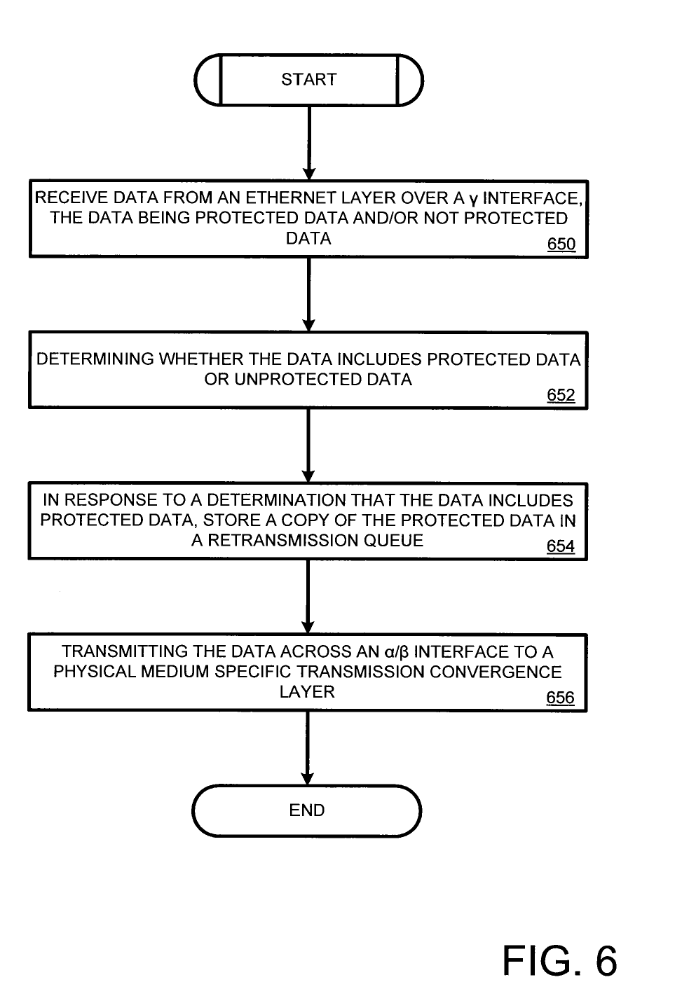

FIG. 6 illustrates an example process that may be utilized for retransmission of data, such as in the computing system of FIG. 1A.

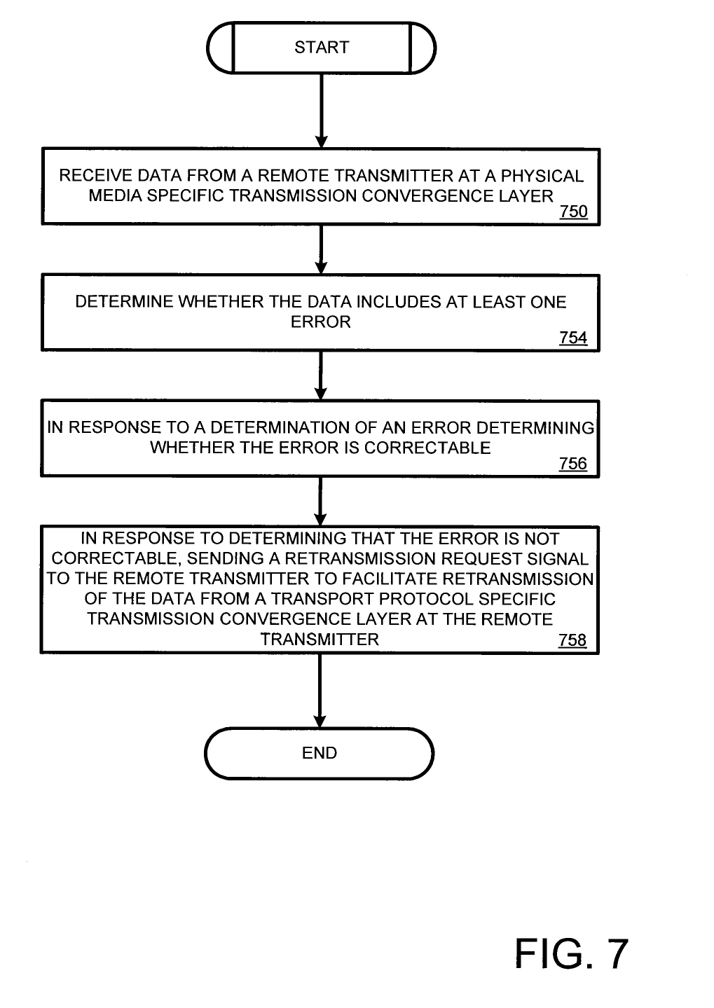

FIG. 7 illustrates an example process that may be utilized by a recipient computing device, such as the computing device depicted in FIG. 1B.

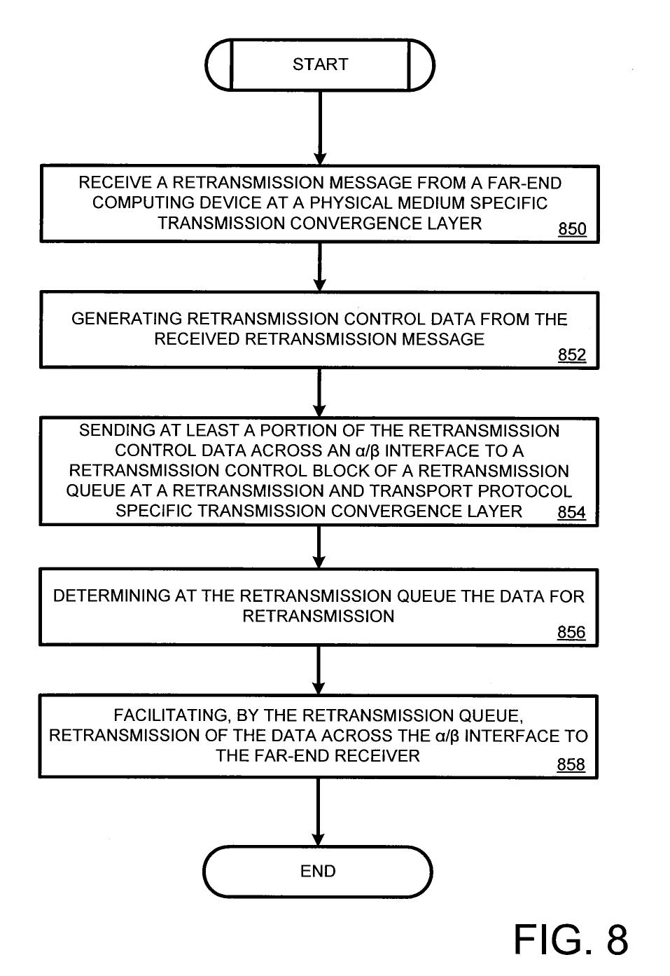

FIG. 8 illustrates an example process that may be utilized in retransmitting data in the computing device depicted in FIG. 1A.

### DETAILED DESCRIPTION

FIG. 1A shows the transmitter reference model for the proposed DSL retransmission method. The operations are split between the PMS-TC (Physical Medium Specific Transmission Convergence) 108 and TPS-TC (Transport Protocol Specific Transmission Convergence) 104. To enable use of traffic differentiation (i.e. content awareness) with retransmission, the formation of the Data Transmission Units (DTUs) and their storage in a retransmission buffer for possible retransmission is done above the TPS-TC layer 104. In an effort to reduce the roundtrip delay, the retransmission control operation is done one layer below the TPS-TC layer 104 in the PMS-TC layer 108. Control information is passed from the PMS-TC layer 108 to the retransmission function 105 across the α/β-interface 116 during each discrete multitone (DMT) Data Symbol Period to facilitate operation of the retransmission mechanism.

At Layer 2 (e.g. the Ethernet Layer), the packets are stored in appropriate priority queues 110 and 112. Data in one or more priority queues 110, 112 may be designated as ‘protected’ by retransmission and others may be designated as ‘not-protected’ by retransmission. The packets are passed to the Retransmission & TPS-TC layer 104 across the γ-interface 114 and the indication of ‘protected’ vs. ‘not-protected’ is passed separately from their respective packet across this same interface.

Inside the Retransmission and TPS-TC layer 104, the packet is fragmented and the resulting fragments are each designated as ‘protected’ or ‘not-protected.’ If the fragment is ‘protected,’ then it is transmitted to the PMS-TC layer 108 via the TPS-TC layer 104 across the α/β-interface 116 and the fragment is also stored in the retransmission buffer 105 for possible retransmission at a later time. If the fragment is ‘not-protected,’ then it is transmitted to the PMS-TC layer 108 via the TPS-TC layer 104 across the α/β-interface 116 and it is NOT stored in the retransmission queue 105.

Note that throughout this application, we use the term ‘fragment’ and ‘data transmission unit (DTU)’ synonymously.

The TPS-TC layer 104 receives the fragment from the retransmission function 105, adds its necessary overhead to identify the beginning and end of a fragment, and then outputs the fragment to the PMS-TC layer 108 at the net-data-rate (Rnet) bit clock across the α/β-interface 116. The net-data-rate is the bit rate at the input to the FEC (i.e. Reed-Solomon Code) block 130. In this paper, we focus on the transport of packets, so the TPS-TC 126 in use is the PTM-TC, which implements 64/65-octet encoding as defined in G.992.3, G.992.5, G.993.2, and IEEE 802.3ah; this is represented in FIG. 1A with the block labeled ‘64/65 Octet.’

As a fragment is transported across the α/β-interface 116 to the PMS-TC layer 108, the fragment is inserted into one or more FEC codeword blocks running synchronously with the net-data-rate clock. The PMS-TC layer 108 has a local (n-bit) counter that counts and identifies each FEC codeword block 130; the counter value is provided back to the Retransmission block 106 so that it may map (i.e. associate) the FEC codeword block count range with the corresponding fragments (DTUs) in the retransmission queue 105.

At the receiver (FIG. 1B), the PMS-TC layer 154 has a counter 159 that is synchronized to the FEC codeword block counter 129 at the transmitter. Synchronization of the two counters is achieved at initialization. The FEC decoder 160 detects each codeword, identifies each as being received correctly (i.e. correctly received with and without correction of errors) or incorrectly (i.e. the correction capability of the FEC code was overbooked for the received codeword), and logs various counts of consecutive correctly received codeword blocks in a defined measurement window. During each DMT Data Symbol Period, synchronous with the DMT Symbol period, the receive PMS-TC block 154 (FIG. 1B) constructs a message describing the number of consecutive correctly received FEC codeword blocks relative to the beginning or the end of the measurement interval, depending on whether the last received codeword in the data symbol period is received correctly or in error. The Retransmission Control message details are provided in the section below on Retransmission Control Operation in the PMS-TC.

At the transmit side, the PMS-TC layer 108 (FIG. 1A) receives the retransmission control messages (“Received Far-end RCC Message” in FIG. 1A) sent from the far-end receiver each Data Symbol period and forwards messages to the retransmission block across the α/β-interface 116 that describes the intervals of correctly and incorrectly received FEC codewords relative to the FEC frame count sequence. The Retransmission Control Channel (RCC) block 134 in the PMS-TC layer 108 forwards a message to the retransmission function 106; based on this information, the retransmission block 106 decides which fragments from the retransmission queue 105 get retransmitted.

If retransmission is supported in the opposite direction, the RCC block 134 receives the FEC error counts from the local receiver (“Near-end Receive FEC error counts” in FIG. 1A) and formulates the retransmission control message for transport to the far-end retransmission function (FIG. 1B).

In the receiver (FIG. 1B), the receive retransmission function implements a rescheduling queue 175 (FIG. 1B) and it is responsible for packet reassembly. When all of the fragments to a packet are received, the fragments are removed from the rescheduling queue 175 (FIG. 1B), reassembled, and forwarded to the upper layer. If there are any missing fragments to a packet that exceed a pre-defined time out period, then the fragments (together with the original packet) are dropped.

Retransmission Control Operation in PMS-TC

The PMS-TC layer 108 (FIG. 1A) provides the retransmission control operation, so as to provide a lower roundtrip delay as compared to implementing the retransmission control operation at the TPS-TC layer 104 layer or above. The retransmission control functions provided in the PMS-TC layer 108 include the following:

An FEC codeword block counter 129 in the transmitter that is synchronized with a corresponding FEC codeword block counter in the receiver 159 (FIG. 1B). The FEC codeword block counter values in the transmitter are transmitted to the retransmission function 106 across the α/β-interface 116 so that the retransmission function may identify transmitted fragments with specific FEC codeword blocks. Note that the FEC counter 129 is synchronous to the net-data-rate clock.

In the receiver (FIG. 1B), the retransmission control block 154 monitors the received FEC codeword, and counts a sequence of the correctly received codeword blocks in a measurement interval for reporting to the transmit retransmission function at the far-end

In the transmitter (FIG. 1A), the retransmission control block 134 forwards the retransmission control message received from the far-end retransmission control function 154 (FIG. 1B), checks for any errors in the received message, and forwards appropriate retransmission control information to the retransmission function across the α/β-interface 116.

FEC Codeword Counter and Synchronization

In the PMS-TC layer 108 transmitter, there is an n-bit FEC codeword block counter 129, where n is usually a multiple of 8 (but not necessarily restricted as such). The absolute value of the counter 129 in the transmitter is used by the retransmission function 106 to identify the specific FEC codeword block(s) for which each DTU is being transported. In the receiver (FIG. 1B), there is a corresponding FEC codeword block counter or mechanism that can identify each received FEC codeword block with the same absolute counter value. We refer to the counter value as the Reed-Solomon codeword block Identifier (RSID). The structure of the FEC codeword block is shown in FIG. 2. There are two approaches for synchronizing the RSID counters mentioned in the list below.

The transmitter has a free running FEC counter clock and the corresponding FEC counter clock 132 is synchronized during initialization such that counter values at transmit and receive sides identify the same FEC codeword block.

The RSID of the specific FEC codeword is passed in the data field of the codeword, such that the k bytes in data field of an (N_{FEC}, k) RS code contains n/8 bytes for the RSID and k−n/8 bytes of actual data.

The synchronization technique used may be directly configured or negotiated at initialization.

Retransmission Control Channel

During each data symbol period, the receive retransmission control block in the PMS-TC layer 154 monitors the received FEC codeword blocks and constructs a message for transmission to the far-end retransmission control block in the transmit PMS-TC layer 108 so as to provide an indication of the quality of the received FEC codeword blocks. The retransmission function at the transmitter uses this information to determine which fragments or DTUs, if any, need to be retransmitted. The message field contains N_{RCC} bits and a message is sent each DTU Data Symbol Period.

FIG. 3 shows the frame structure of the RCC message. The first bit labeled ACK/NACK identifies the reception of correct or incorrect received FEC codewords in the FEC codeword block. The RSID field (Field 2) identifies the last completely received FEC codeword block received during the current data symbol. Note that the number of bits in this field is M1 bits, where M1≦n (the number of bits in the RSID counter) represents the M1 least significant bits of the n-bit FEC codeword block counter. If the FEC codeword block is received error free (i.e. no uncorrected FEC errors) then Field 3 contains a count of last consecutive FEC codeword blocks received without errors; the maximum number in this field is 2^{M2}−1 FEC codewords. If the FEC codeword block is received with one or more errors (i.e. with uncorrected FEC errors) then Field contains a count of consecutive FEC codeword blocks received error free directly following and including the preceding (2^{M2}−1)^{th} FEC codeword block.

An example configuration of the RCC message frame is 24 bits for the total frame, i.e. N_{RCC}=24 bits; M1=5 bits (these are the 5 least significant bits of the n-bit FEC codeword block counter); M2=6 bits; and M3=12 bits for error detection. The error detection may be implemented with any desired code, e.g. a cyclic redundancy check (CRC), Golay Code, etc.

Also, to simplify reporting and identification of FEC codeword blocks, it is recommended (but not required) that the FEC codeword block size be greater than one-half of a DMT Data Symbol Period so as to avoid having more than one codeword block within a data symbol period.

Retransmission Operation in TPS-TC

In the case of Packet Transfer Mode (PTM), the DTUs are generally fragments of Ethernet packets. The fragments (also referred to as DTUs) are constructed per the rules of Ethernet Bonding as defined in G.998.2. The structure of a PTM data fragment (DTU) is shown below in FIG. 4. These fragments are the fundamental elements stored in the retransmission buffer within the transmitter together with locally stored status and control information for each DTU.

DTUs are transported on the DSL link in FEC codeword blocks within the PMS-TC layer 108. The FEC codeword block counter (RSID) values are provided by the PMS-TC layer 108 to the retransmission function across the α/β-interface 116. The retransmission function stores the DTUs designated as ‘protected’ in the retransmission and keeps a mapping of the associated RSID(s) as provided by the PMS-TC layer 108 through the α/β-interface 116. FIG. 5 shows an example of the mapping for the FEC codeword block that a DTU is transported through the PMS-TC layer 108 that the retransmission function will need to keep track of.

During each DMT Symbol period, the PMS-TC layer 108 sends an RCC message to the retransmission function across the α/β-interface 116. Through the series of RCC messages received from the PMS-TC layer 108, the retransmission function determines the time intervals of FEC codeword blocks that have been received in error, identifies the transmitted DTUs stored in the retransmission that were affected and retransmits the affected DTUs.

Together with each stored DTU in the retransmission queue 105, there is a status assigned to each DTU that is managed by the retransmission function. The status elements may include (but not limited to) the RSID mapping, whether a DTU has been retransmitted or not, and a Timeout value. If a DTU is stored for too long a period of time in the retransmission queue, then a retransmission of that DTU may exceed the allocated end to end delay limit. Therefore, if a time period is exceeded for any DTU in the retransmission queue 105, the DTU is dropped and not retransmitted.

In operation of at least one nonlimiting example, data packets from layer 2 may be determined as protected or not protected and accordingly stored in priority queue 1 110 or priority queue 2 112. The data in priority queues 110 and 112 may be multiplexed by multiplexor 118 and sent across the γ interface 114 to the fragment component 115 for fragmentation. After fragmentation, the DTUs may be sent to a multiplexor 120. The multiplexor selects between protected data and unprotected data. If protected data is selected, the selected protected data may be multiplexed by a multiplexor 122, along with retransmission data from the retransmission queue 105. If the multiplexor 122 selects the protected data, this data is sent to both the retransmission queue 105 (for storage) and to a multiplexor 124. If the multiplexor 122 selects the retransmitted data from the retransmission queue 105, this data may be sent to multiplexor 124. The multiplexor 124 may select between the unprotected data from the multiplexor 120 and the data selected from the multiplexor 122. The data from the multiplexor 124 may be sent to a TPS-TC block 126.

Regardless of whether protected data, retransmission data or not protected data is received at the TPS-TC block 126, the TPS-TC block 126 receives the DTUs, adds an overhead byte (to create a 65 byte fragment from a 64 byte fragment) for PTM control that identifies a beginning and end of the fragment. The TPS-TC block 126 then outputs the 65 byte fragment to a scrambler block 128 on the PMS-TC layer 108 at a net-data-rate (Rₙₑₜ) bit clock across the α/β-interface 116. The data is sent to the FEC encoder 130 and then to an interleaver 136 to be sent to the far-end receiver, via block 135.

At the far-end receiver, a PMS-TC layer 154 associated with a far-end receiver computing device may receive the data from the multiplexor 135 (FIG. 1A). This data may be separated out from the overhead data via block 155. The payload data may then be sent to a deinterleaver 166, an FEC decoder 160, and a de-scrambler 158, which are synchronized according to a data clock source 152. When the FEC decoder 160 receives that data from the deinterleaver 166, the FEC decoder 160 can determine whether there are any errors in the received data. If there are errors, a determination is made regarding whether the errors can be corrected by the FEC decoder 160. If so, they are fixed accordingly. If however, the errors are not correctable by the FEC decoder 160, the FEC decoder sends data regarding the data with errors to an RCC block 154, which also receives data frame clock signal to identify which data includes the errors.

Upon receiving the data from the FEC decoder 160, the RCC block 154 (which may include a counter 159) can create an RCC message to be sent (along with uplink overhead) to the RCC block 134 (FIG. 1A) to facilitate retransmission of the data, via block 157.

If the FEC decoder 160 determines that there are no uncorrectable errors, the FEC decoder 160 can decode the data and send the decoded data to the de-scrambler 158. After de-scrambling, the data may be sent across an α/β interface 146 to a 65/64 octet block 156 and then to a demultiplexor 161. The demultiplexor 161 can determine whether the received data is protected data or unprotected data. The protected data can be sent to a rescheduling buffer 175 for reordering. The reordered data may then be sent to a reassemble packets block 176 for reassembly. If the data at demultiplexor 161 is unprotectable (not eligible for retransmission), the data may be sent directly to the reassemble packets block 176 for reassembly. From the reassemble packets block 176, the data (whether protected or unprotected) may be sent across a γ interface 144.

FIG. 6 illustrates an example process that may be utilized for retransmission of data, such as in the computing system of FIG. 1A. As illustrated in the nonlimiting example of FIG. 6, data may be received from an Ethernet layer over the γ interface, the data being protected data or not protected data (block 650). Additionally, a determination can be made regarding whether the data includes protected or unprotected data (block 652). In response to a determination that the data includes protected data, a copy of the protected data can be stored in a retransmission queue (block 654). Additionally, the data can be transmitted across an α/β interface to a PMS-TC layer 108 (block 656).

FIG. 7 illustrates an example process that may be utilized by a recipient computing device, such as the computing device depicted in FIG. 1B. As illustrated in the nonlimiting example of FIG. 7, data can be received from a remote transmitter at a PMS-TC layer 154 on a far-end receiver (block 750). A determination can be made (e.g., by the FEC decoder 160) regarding whether the data includes at least one error (block 754). In response to a determination of an error, a determination can be made regarding whether the error is correctable (e.g., at the FEC decoder 160—block 756). In response to a determination that the error is not correctable, sending (e.g., via RCC block 154) a retransmission request signal to the remote transmitter to facilitate retransmission of the data from a transport PMS-TC layer 108 at the remote transmitter (block 758).

FIG. 8 illustrates an example process that may be utilized in retransmitting data in the computing device depicted in FIG. 1A. As illustrated in the nonlimiting example of FIG. 8, a retransmission message from a far end computing device may be received at a PMS-TC layer 108 (block 850). Retransmission control data may be generated (e.g., via RCC block 134) from the received retransmission message (block 852). At least a portion of the retransmission control data can be sent over an α/β interface 116 to a retransmission control block 106 of a retransmission queue 105 at a retransmission and TPS-TC layer 104 (block 854). A determination can be made at the retransmission queue 105 regarding the data requested for retransmission (block 856). Additionally, the retransmission queue 105 can facilitate retransmission of the data across the α/β interface to the far-end receiver (block 858).

The embodiments disclosed herein can be implemented in hardware, software, firmware, or a combination thereof. At least one embodiment disclosed herein may be implemented in software and/or firmware that is stored in a memory and that is executed by a suitable instruction execution system. If implemented in hardware, one or more of the embodiments disclosed herein can be implemented with any or a combination of the following technologies: a discrete logic circuit(s) having logic gates for implementing logic functions upon data signals, an application specific integrated circuit (ASIC) having appropriate combinational logic gates, a programmable gate array(s) (PGA), a field programmable gate array (FPGA), etc.

One should also note that conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more particular embodiments or that one or more particular embodiments necessarily include logic for deciding, with or without user input or prompting, whether these features, elements and/or steps are included or are to be performed in any particular embodiment.

It should be emphasized that the above-described embodiments are merely possible examples of implementations, merely set forth for a clear understanding of the principles of this disclosure. Many variations and modifications may be made to the above-described embodiment(s) without departing substantially from the spirit and principles of the disclosure. Further, the scope of the present disclosure is intended to cover all combinations and sub-combinations of all elements, features, and aspects discussed above. All such modifications and variations are intended to be included herein within the scope of this disclosure.

Therefore, at least the following is claimed:

1. A method, comprising:
receiving data from above a γ (gamma) interface, the data being identified as protected or not protected data;
fragmenting the data into protected and unprotected fragments with a fragment component configured to receive protected and unprotected data;
storing the protected fragment in a retransmission queue included in a transport protocol specific transmission convergence layer;
transmitting the protected and non-protected fragments across an α/β (alpha/beta) interface to a physical medium specific transmission convergence layer; and
in response to an indication for retransmission of a fragment, the indication coming from a physical medium specific transmission convergence layer, determining whether the fragment is protected, locating the fragment in the retransmission queue, and retransmitting the protected fragment across an α/β interface to a physical medium specific transmission convergence layer.

2. The method of claim 1, wherein all fragments are protected.

3. The method of claim 1, further comprising receiving the indication for retransmission of the fragment, the indication being received from a retransmission control channel.

4. The method of claim 1, wherein the indication for retransmission coming from a physical medium specific transmission convergence (PMS-TC) layer is associated with PMS-TC error detection blocks that are not necessarily aligned with fragments; and wherein a transport protocol specific-transmission convergence (TPS-TC) layer includes a retransmission control block that maps PMS-TC error detection blocks with the corresponding fragments in the retransmission queue and takes the decision to retransmit fragments corresponding to PMS-TC error detection blocks identified as incorrectly received by the far-end receiver device.

5. The method of claim 4, wherein each PMS-TC error detection block is formed of at least one FEC codewords.

6. The method of claim 1, wherein the retransmission control block is synchronized with the PMS-TC layer via a FEC codeword counter that is synchronized with a corresponding FEC codeword counter in the far-end receiver.

7. A method, comprising:
receiving data at a physical medium specific transmission convergence layer, and determining whether there is any error in the received data;
in response to a determination that the data includes at least one error, determining whether the error can be corrected with a forward error correction decoder and,
in response to a determination that the error cannot be corrected with the forward error correction decoder, constructing an indication to a far-end transmitter device for retransmitting at least a portion of the data received in error; and
in response to determination that the data includes no error or the error can be corrected with the forward error correction decoder, the data is sent across an α/β (alpha/beta) interface for rescheduling in a transport protocol specific transmission convergence layer.

8. The method of claim 7, wherein an error in the received data is determined when at least one FEC codeword has at least one error.

9. The method of claim 7, wherein the indication for retransmitting at least a portion of the data sent to a far-end transmitter includes a count of received FEC codewords, and an indication of whether the FEC codewords were received correctly or incorrectly.

10. The method of claim 7, wherein the indication for retransmitting at least a portion of the data received in error is sent to the far-end transmitter in each of a plurality of discrete multitone (DMT) symbol frames.

11. The method of claim 7, wherein not-protected data sent across the α/β interface is sent across the gamma interface, without being sent to the rescheduling queue.

12. A system, comprising:
a retransmission and transport protocol specific-transmission convergence (TPS-TC) layer configured to receive data from above a γ (gamma) interface, the data being identified as protected or not protected data;
a fragment component in the retransmission and TPS-TC layer configured to fragment the data into protected and unprotected fragments with a fragment component configured to receive protected and unprotected data;
a retransmission queue in the retransmission and TPS-TC layer configured to store the protected fragment in a retransmission queue included in a transport protocol specific transmission convergence layer;
a TPS-TC component in the retransmission and TPS-TC layer configured to transmit the protected and non-protected fragments across an α/β (alpha/beta) interface to a physical medium specific transmission convergence (PMS-TC) layer; and
a retransmission control component in the retransmission and TPS-TC layer configured to, in response to an indication for retransmission of a fragment coming from a physical medium specific transmission convergence layer:
determine whether the fragment is protected;
locate the fragment in the retransmission queue; and
retransmit the protected fragment across the α/β (alpha/beta) interface to the PMS-TC layer.

13. The system of claim 12, wherein all fragments are protected.

14. The system of claim 12, wherein the indication for retransmission of a fragment comes from the PMS-TC layer.

15. The system of claim 14, wherein the indication for retransmission coming from the PMS-TC layer is associated with PMS-TC error detection blocks that are not necessarily aligned with fragments; and wherein a transport protocol specific-transmission convergence (TPS-TC) layer includes a retransmission control block that maps PMS-TC error detection blocks with the corresponding fragments in the retransmission queue and takes the decision to retransmit fragments corresponding to PMS-TC error detection blocks identified as incorrectly received by the far-end receiver device.

16. The system of claim 15, wherein each PMS-TC error detection block is formed of at least one FEC codewords.

17. The system of claim 15, further comprising a forward error correction (FEC) codeword counter configured to synchronize the retransmission control block with the PMS-TC layer, the FEC codeword counter being synchronized with a corresponding FEC codeword counter in the far-end receiver.

18. The system of claim 12, wherein the indication for retransmitting a fragment includes a count of received FEC codewords and an indication of whether the FEC codewords were received correctly or incorrectly.

19. The system of claim 12, wherein the indication of retransmitting the fragment is received in each of a plurality of discrete multitone (DMT) symbol frames.

20. The system of claim 12, further comprising a retransmission control channel configured to send the indication for retransmission to the retransmission control component.
